(19) United States
(12) Patent Application Publication
(10) Pub. No.: US 2017/0184628 A1
(43) Pub. Date: Jun. 29, 2017

(54) MICRO-ELECTROMECHANICAL APPARATUS HAVING CENTRAL ANCHOR

(71) Applicant: Industrial Technology Research Institute, Hsinchu (TW)

(72) Inventors: Yu-Wen Hsu, Tainan City (TW); Chung-Yuan Su, Taichung City (TW); Chao-Ta Huang, Hsinchu City (TW)

(73) Assignee: Industrial Technology Research Institute, Hsinchu (TW)

(21) Appl. No.: 15/252,226

(22) Filed: Aug. 31, 2016

Related U.S. Application Data
(60) Provisional application No. 62/271,329, filed on Dec. 28, 2015.

(30) Foreign Application Priority Data
Dec. 28, 2015 (TW) 104143997

(51) Int. Cl. G01P 15/18; G01P 15/08; B81B 3/00

(52) U.S. Cl. CPC G01P 15/18; B81B 3/0062; G01P 15/08; B81B 2201/0235; B81B 2203/0307; B81B 2203/04; B81B 2203/051; B81B 2203/053; B81B 2203/055; B81B 2203/0163

(57) ABSTRACT

A micro-electromechanical (MEMS) apparatus includes a substrate, two first anchors, a frame, and two elastic members. The substrate is provided with a reference point thereon. The frame surrounds the two first anchors, and each of the elastic members connects the corresponding first anchor and the frame. Each of the first anchors is disposed near the center of the MEMS apparatus to decrease an effect caused by warpage of the substrate. The MEMS apparatus can be applied to an MEMS sensor having a rotatable mass, such as a three-axis accelerometer or a magnetometer, to improve process yield, reliability, and measurement accuracy.

### CROSS-REFERENCE TO RELATED APPLICATION

This application claims the priority benefits of U.S. provisional application Ser. No. 62/271,329, filed on Dec. 28, 2015 and Taiwan application serial no. 104143997, filed on Dec. 28, 2015. The entirety of each of the above-mentioned patent applications is hereby incorporated by reference herein and made a part of this specification.

### BACKGROUND

Technical Field

The disclosure relates to a micro-electromechanical (MEMS) apparatus, and more particularly, to an MEMS apparatus having a central anchor.

Background

In recent years, because electronic products, such as smart phones, tablet PCs, interactive game consoles, and etc., have started using micro-electromechanical (MEMS) inertial sensing elements (such as an accelerometer and gyroscope), a market demand for the MEMS inertial sensing elements has grown rapidly. On the condition that the process technology and related products for the accelerometer have become relatively matured, process yield during mass production has become an important competitive factor in the market of the MEMS inertial sensors.

In terms of MEMS apparatus manufacturing, one of the currently encountered problems is that: when using the wafer-to-wafer process to manufacture the MEMS apparatus or during the subsequent operation of the MEMS apparatus, a substrate will warp due to thermal stress. For instance, in a conventional MEMS apparatus 100 as shown in FIG. 1, a sensing mass 120 and an anchor 130 are arranged on a substrate 110, and the anchor 130 is located outside the sensing mass 120 and supports the sensing mass 120 via a torsional beam 140. When the substrate 110 warps or deforms due to the thermal stress, the anchor 130 may be displaced or deformed following the deformation of the substrate 110. Critical errors arise accordingly when the MEMS apparatus measures physical quantities (e.g., acceleration) with use of the sensing mass 120.

### SUMMARY

The disclosure is directed to a micro-electromechanical (MEMS) apparatus which is able to reduce the effect caused by warpage of a substrate, increase process yield and product reliability, and improve measurement accuracy.

The disclosure is directed to an MEMS apparatus which is able to reduce the number of anchors used and minimize an area of the MEMS apparatus.

According to one of exemplary embodiments, an MEMS apparatus includes a substrate, two first anchors, a frame, and two elastic members. The two first anchors are disposed on the substrate, and a distance from each of the first anchors to a reference point of the substrate is equal. In addition, the frame surrounds the two first anchors, and each of the two first anchors is connected to the frame through one of the corresponding two elastic members. The distance from each of the first anchors to the reference point is less than a distance from each of the first anchors to the frame.

According to one of exemplary embodiments, another MEMS apparatus includes a substrate, two first anchors, a frame, at least one central mass, and two elastic members. The two first anchors are disposed on the substrate, and a distance from each of the first anchors to a reference point of the substrate is equal. The frame surrounds the two first anchors. The at least one central mass includes a central portion and at least one side portion. Each of the two first anchors is connected to the frame through one of the corresponding two elastic members, and the distance from each of the first anchors to the reference point is less than a distance from each of the first anchors to the frame.

According to one of exemplary embodiments, another MEMS apparatus adapted for measuring three-axis acceleration is provided. The MEMS apparatus includes a substrate, two first anchors, at least one second anchor, a frame, at least one central mass, and two elastic members. The two first anchors are disposed on the substrate, and a distance from each of the first anchors to a reference point of the substrate is equal. The at least one second anchor is disposed on the substrate. The at least one central mass includes a central portion and at least one side portion. The frame surrounds the two first anchors and the at least one central mass. Each of the two first anchors is connected to the frame through one of the corresponding two elastic members, wherein the distance from each of the first anchors to the reference point is less than a distance from each of the first anchors to the frame. In addition, a distance from the at least one second anchor to the reference point is less than a distance from the at least one second anchor to the frame.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional diagram illustrating a conventional MEMS apparatus.

FIG. 2 is a schematic diagram illustrating an MEMS apparatus according to an exemplary embodiment.

FIG. 3 is a schematic diagram illustrating an MEMS apparatus according to another exemplary embodiment.

FIG. 4 is a schematic diagram illustrating an MEMS apparatus according to another exemplary embodiment.

FIG. 5 is a schematic diagram illustrating an MEMS apparatus according to another exemplary embodiment.

FIG. 6 is a schematic diagram illustrating an MEMS apparatus according to another exemplary embodiment.

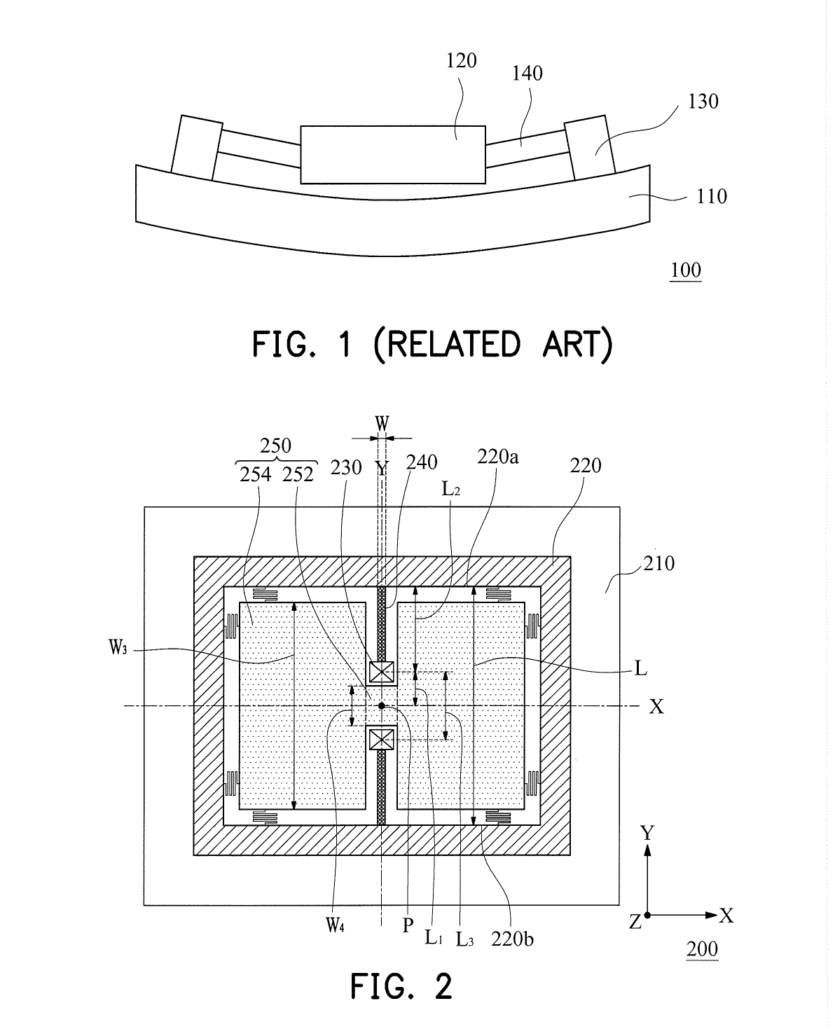

### DETAILED DESCRIPTION OF DISCLOSED EMBODIMENTS

A micro-electromechanical (MEMS) apparatus of the disclosure is suitable for measuring physical quantities of inertia, i.e., measuring physical quantities (e.g., acceleration, angular velocity, a geomagnetic force, a resonance frequency, and so forth) based on inertia of mass. Although several possible implementations are illustrated in the following exemplary embodiments, the actual number, the shape, and the location of the mass or other components of the MEMS apparatus can be changed in response to the occasions of application and the demands and are not limited by the following exemplary embodiments. Modifications and variations based on these exemplary embodiments of the disclosure can be made by people having ordinary skill in the pertinent art according to the level of technology at the time of the application after they are exposed to the contents of the disclosure.

FIG. 2 is a schematic diagram illustrating an MEMS apparatus 200 according to an exemplary embodiment. The MEMS apparatus 200 includes a substrate 210, a frame 220, two first anchors 230, and two elastic members 240. In the present embodiment, the two first anchors 230 are surrounded by the frame 220 and are disposed near the central position of the MEMS apparatus 200, so as to reduce the effect caused by the thermal stress and warpage of the substrate 210. Furthermore, a reference point P of the substrate 210 is defined on a line connecting central point of each of the two first anchors 230. A distance L₁ from each of the first anchors 230 to the reference point P is equal. Herein, if a surface of the substrate 210 is defined to be the X-Y plane, then the origin of an X-Y plane coordinate system can be set at the reference point P, and the Y-axis can be defined as an axis passing through the central point of each of the first anchors 230 and the reference point P.

The two elastic members 240 respectively connect the corresponding first anchors 230 and the frame 220, so that the frame 220 can be suspended above the substrate 210. In addition, the distance L₁ from each of the first anchors 230 to the reference point P is less than a distance L₂ from each of the first anchors 230 to the frame 220. In other words, as compared to the frame 220, the first anchors 230 are closer to the reference point P.

In the present embodiment, the two elastic members 240 may be two torsional beams, so that the frame 220 can be rotated along the elastic members 240. As such, the frame 220 may, for example, be applied for sensing a Z-axis acceleration perpendicular to the plane of the substrate 210. In other exemplary embodiments of the disclosure, the elastic members 240 may also be elastic members such as connecting rods, springs (e.g., folding springs), or so forth.

In the present embodiment, the first anchors 230 are disposed near the central position of the MEMS apparatus 200 to reduce effects caused by the warpage of the substrate 210 during a wafer-to-wafer bonding process, which helps facilitate an increase in process yield. More specifically, when the distance L₁ from each of the first anchors 230 to the reference point P is less than the distance L₂ from each of the first anchors 230 to the frame 220, the two elastic members 240 (e.g., torsion beams) may not be affected significantly by the warpage of the substrate 210. Thus, the MEMS apparatus 200 provides high accuracy of Z-axis acceleration measurement. To further reduce the aforementioned effect, several locations of the first anchors 230 are disclosed in the present embodiment. As shown in FIG. 2, in a direction of line connecting the two first anchors 230 (e.g., the Y-axis direction provided in the present embodiment), a distance from an inner side 220a of the frame 220 to another inner side 220b of the frame 220 is defined as L and a distance between the two first anchors 230 is defined as L₃. When the distance L₃ is less than L/4, the effect caused by the warpage of the substrate 210 is further reduced.

For example, the two elastic members 240 may be torsion beams as shown in FIG. 2. When the area of the MEMS apparatus 200 is reduced, the width W of the elastic members 240 is decreased accordingly for the purpose of decreasing the rigidity. However, if the width W of the elastic members 240 is reduced, the process yield of the MEMS apparatus 200 will be decreased. In the present embodiment, the distance L₃ between the two first anchors 230 is less than L/4 to make the length of elastic members 240 enough to reduce the rigidity of the elastic members 240. By the smaller rigidity of the elastic members 240, the frame 220 rotates with a larger angular angle when the Z-axis acceleration is measured. In other words, when the distance L₃ between the two first anchors 230 is less than L/4, the MEMS apparatus 200 provides higher sensitivity of Z-axis acceleration measurement without decreasing the process yield and reliability.

Furthermore, in the present embodiment, one or more masses may be selectively disposed in the frame 220 to measure the different physical quantities such as accelerations in the X-axial direction and the Y-axial direction. As shown in FIG. 2, a central mass 250 is disposed in the frame 220. Since one portion of the central mass 250 is in a space between the two first anchors 230, an overall area of the MEMS apparatus 200 may be reduced without reducing the sensitivity of acceleration measurement in the X-axial direction or the Y-axial direction. More specifically, the central mass 250 may include a central portion 252 which is disposed between the two first anchors and two side portions 254 each connect one corresponding side of the central portion 252 respectively. In the present embodiment, a width W₃ of the side portions 254 is, for example, greater than a width W₄ of the central portion 252. The width W₃ of the side portions 254 is defined as a dimension between two sides of the side portions 254 as shown in FIG. 2, where the dimension between two sides of the side portions 254 are parallel to the line connecting the two first anchors 230. The width W₄ of the central portion 252 is defined as a dimension between two sides of the central portion 252, where the dimension between two sides of the central portion 252 are parallel to the line connecting the two first anchors 230.

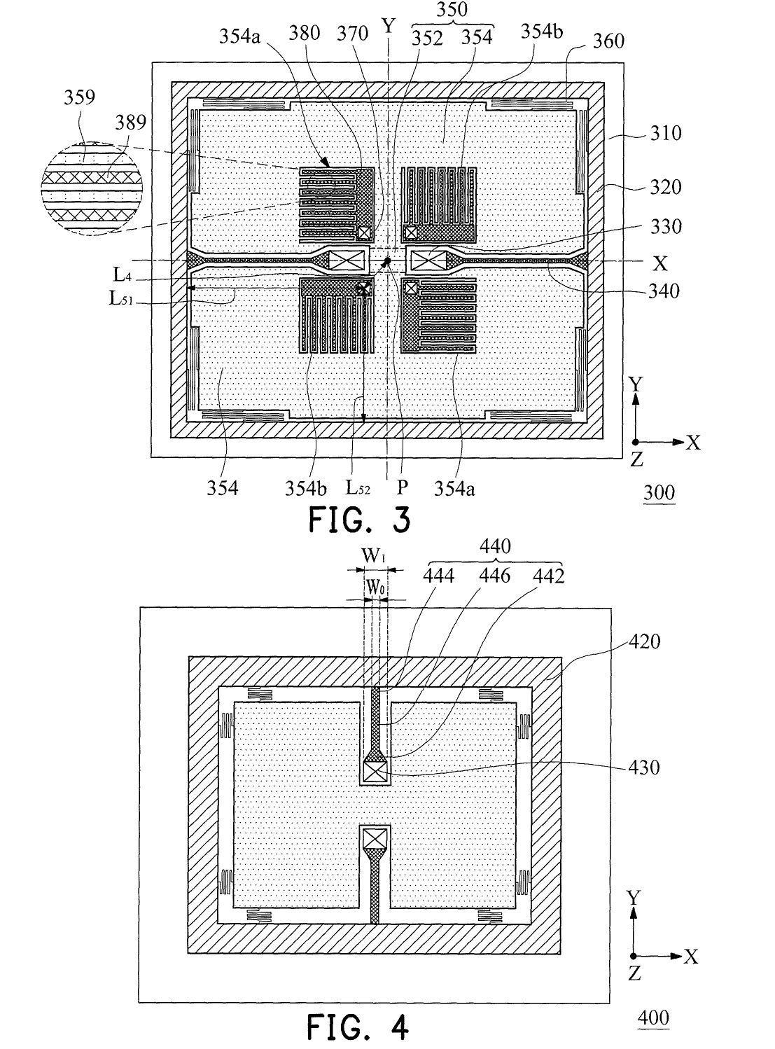

FIG. 3 further illustrates an embodiment which adapts the MEMS apparatus 200 to measure the accelerations in three axes. Since an MEMS apparatus 300 provided in the present embodiment is varied from the MEMS apparatus 200 provided in the previous embodiment, features and effects mentioned in the previous embodiment will not be repeated herein. Only the details of the present embodiment highlighted in FIG. 3 are provided.

In the present embodiment, the frame 320 is suspended above the substrate 310 via the two elastic members 340 that serve as the torsional beams which enable the frame 320 to measure a Z-axis acceleration. On the other hand, the central mass 350 is surrounded by the frame 320 and connected to the frame 320 via a plurality of springs 360 (e.g., folded springs). The central mass 350 is used to measure an X-axis acceleration and a Y-axis acceleration simultaneously.

In addition, the present embodiment further includes one or a plurality of second anchors 370 and one or a plurality of stationary electrodes 380 which are used for measuring the X-axis acceleration and the Y-axis acceleration. More specifically, as shown in FIG. 3, the two side portions 354 have two openings 354a and 354b respectively. Each opening 354a or 354b accommodates one stationary electrode 380 and one second anchor 370. The stationary electrode 380 is connected to the second anchor 370 and is suspended above the substrate 310.

In the present embodiment, a distance L₄ from each of the second anchors 370 to the reference point P is less than a distance from each of the second anchors 370 to the frame 320. More specifically, the distance from each of the second anchors 370 to the frame 320 is defined as the smaller one of two distances (a distance L₅₁ and a distance L₅₂), wherein the distance L₅₁ is defined as the distance from each of the second anchors 370 to the inner side of the frame 320 along the X-axis and the distance L₅₂ is defined as the distance from each of the second anchors 370 to the inner side of the frame 320 along the Y-axis. In other words, in the present embodiment, the second anchors 370 are disposed close to the central region of the MEMS apparatus 300 to reduce the effect caused by warpage of the substrate 310. In addition, the central mass 350 includes a plurality of first finger-shaped structures 359, and each of the stationary electrodes 380 includes a plurality of second finger-shaped structures 389. The capacitance between a plurality of first finger-shaped structures 359 and a plurality of second finger-shaped structures 389 is changed when the central mass 350 is moved. Moreover, the first finger-shaped structures 359 and the second finger-shaped structures 389 corresponding to one opening 354a and the first finger-shaped structures 359 and the second finger-shaped structures 389 corresponding to another opening 354b are disposed in different extending directions in order to measure the accelerations in the X-axial direction and the Y-axial direction.

FIG. 4 is a schematic diagram illustrating an MEMS apparatus according to another exemplary embodiment. As shown in FIG. 4, an MEMS apparatus 400 provided in the present embodiment is similar to the MEMS apparatus 200 provided in the previous embodiment. A main difference between the two embodiments is the elastic members.

More specifically, the present embodiment introduces the elastic members 440 with a width variation to prevent the frame 420 from rotating along the Z-axis which affects the accuracy of Z-axis acceleration measurement. Each of the elastic members 440 provided in the present embodiment includes a fixed end 442, a movable end 444, and a connecting portion 446. The fixed end 442 is connected to the corresponding first anchor 430. The movable end 444 is connected to the frame 420. The connecting portion 446 connects the fixed end 442 and the movable end 444. A width W₁ of the fixed end 442 (i.e., the maximum width of the fixed end 442) is greater than a width W₀ of the connecting portion 446. In the present embodiment, the width of the elastic members 440 is increased from the connecting portion 446 towards the first anchor 430 to prevent the frame 420 from rotating along the Z-axis and to prevent the fixed end 442 from cracking. Therefore, the elastic members 440 with the varied width not only can reduce the stress in the fixed ends 442, but also can maintain the sensitivity of the Z-axis acceleration measurement.

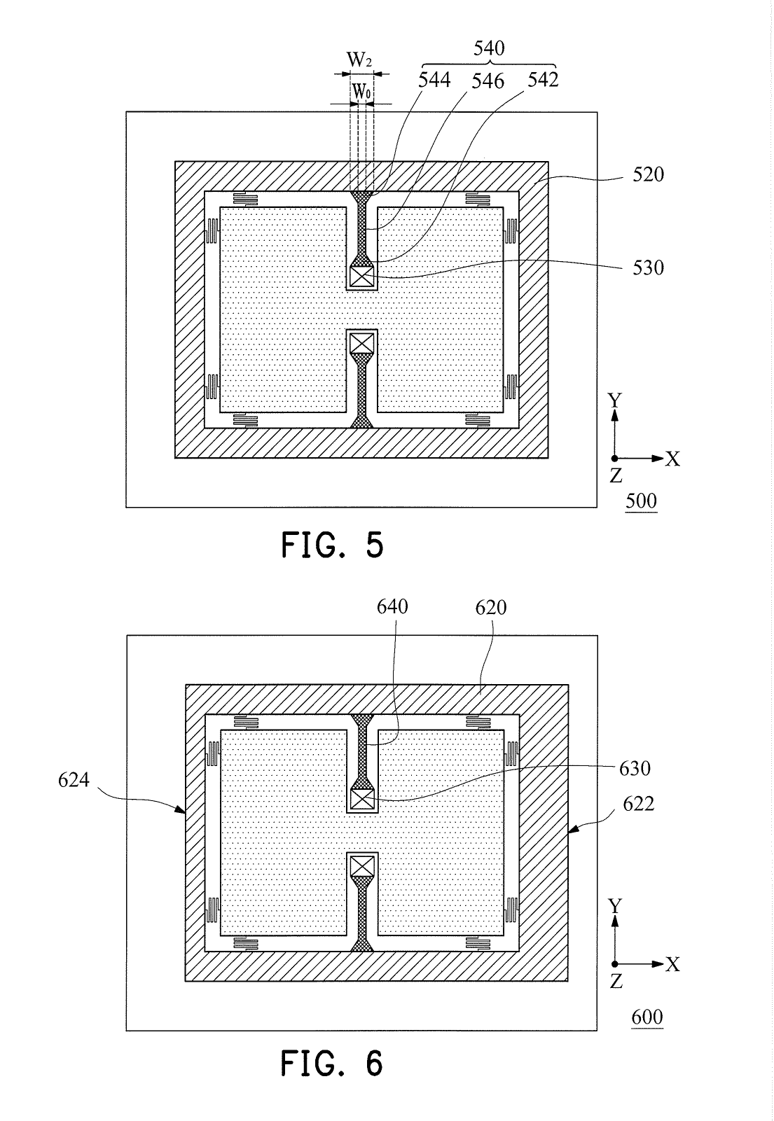

FIG. 5 is a schematic diagram illustrating an MEMS apparatus according to another exemplary embodiment. As shown in FIG. 5, an MEMS apparatus 500 provided in the present embodiment is similar to the MEMS apparatus 400 provided in the previous embodiment, and a main difference between the two embodiments is the elastic members.

Each of the elastic members 540 provided in the present embodiment includes a fixed end 542, a movable end 544, and a connecting portion 546. The fixed end 542 is connected to the corresponding first anchor 530. The movable end 544 is connected to the frame 520. The connecting portion 546 connects the fixed end 542 and the movable end 544. In the present embodiment, the width of the fixed end 542 and the width of the movable end 544 are increased. A width W₂ of the movable end 544 is defined as the maximum width of the movable end 544. The width W₂ of the movable end 544 is greater than the width W₀ of the connecting portion 546. For example, in the present embodiment, the width of the movable end 544 is gradually increased from the connecting portion 546 towards the frame 520 in order to prevent the movable end 544 and the frame 520 from cracking.

FIG. 6 is a schematic diagram illustrating an MEMS apparatus according to another exemplary embodiment. As shown in FIG. 6, an MEMS apparatus 600 provided in the present embodiment is similar to the MEMS apparatus 500 provided in the previous embodiment, and a main difference between the two embodiments is the structure of the frame.

More specifically, the frame 620 in the present embodiment may be an unbalanced mass when a line connecting the two first anchor 630 does not pass through the center of gravity of the frame 620. For instance, as shown in FIG. 6, when the distance from each of the elastic members 640 to the inner side of the frame 620 remains the same and one side 622 of the frame 620 is wider than another side 624 of the frame 620, the frame 620 is an unbalanced mass since the line connecting the two first anchor 630 does not pass through the center of gravity of the frame 620. In other exemplary embodiments (not shown), the frame 620 may be an unbalanced mass when the side 622 of the frame 620 is thicker than another side 624 of the frame 620. With the unbalanced frame 620, the MEMS apparatus 600 can have a higher sensitivity of Z-axis acceleration measurement.

In summary, the first anchors and the second anchor provided in the disclosure are disposed close to the central region of the MEMS apparatus to reduce the effect of substrate warpage and to increase the process yield. Moreover, in the disclosure, the width of the elastic members can be designed to prevent the frame from rotating along the Z-axis. On the other hand, the MEMS apparatus provided in the disclosure may be applied in an MEMS sensor having a rotatable mass, such as a three-axis accelerometer, a magnetometer, or so forth. In addition, the central mass adapted for sensing the X-axis and Y-axis accelerations may be connected to the frame and is suspended above the substrate through a plurality of springs without using additional anchors. The area of the MEMS apparatus is reduced by reducing the number of the anchor.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A micro-electromechanical apparatus, comprising:
a substrate;
two first anchors disposed on the substrate, wherein a distance from each of the first anchors to a reference point of the substrate is equal;
a frame surrounding the two first anchors; and
two elastic members wherein each of the two first anchors is connected to the frame through corresponding one of the two elastic members,
wherein the distance from each of the first anchors to the reference point is less than a distance from each of the first anchors to the frame.

2. The micro-electromechanical apparatus as recited in claim 1, wherein a distance from an inner side of the frame to another inner side of the frame is L, and a distance between the two first anchors is less than L/4.

3. The micro-electromechanical apparatus as recited in claim 1, wherein each of the elastic members comprises:
a fixed end connected to the corresponding first anchor;
a movable end connected to the frame; and
a connecting portion connected to the fixed end and the movable end, wherein a width of the fixed end is greater than a width of the connecting portion.

4. The micro-electromechanical apparatus as recited in claim 3, wherein a width of the movable end is greater than the width of the connecting portion.

5. The micro-electromechanical apparatus as recited in claim 1, further comprising at least one second anchor, wherein the at least one second anchor is disposed on the substrate, and a distance from the at least one second anchor to the reference point is less than a distance from the at least one second anchor to the frame.

6. The micro-electromechanical apparatus as recited in claim 5, further comprising at least one stationary electrode, wherein the at least one stationary electrode is connected to the at least one second anchor and is suspended above the substrate.

7. The micro-electromechanical apparatus as recited in claim 5, further comprising at least one central mass, wherein the at least one central mass comprises a central portion and at least one side portion, the central portion is disposed between the two first anchors, and the central portion is connected to the at least one side portion.

8. The micro-electromechanical apparatus as recited in claim 7, wherein a width of the at least one side portion is greater than a width of the central portion.

9. The micro-electromechanical apparatus as recited in claim 7, wherein the at least one side portion comprises at least one opening, and the at least one second anchor is disposed in the at least one opening.

10. A micro-electromechanical apparatus, comprising:
a substrate;
two first anchors disposed on the substrate, wherein a distance from each of the first anchors to a reference point of the substrate is equal;
a frame surrounding the two first anchors;
at least one central mass comprising a central portion and at least one side portion; and
two elastic members wherein each of the two first anchors is connected to the frame through corresponding one of the two elastic members,
wherein the distance from each of the first anchors to the reference point is less than a distance from each of the first anchors to the frame, and the central portion is disposed between the two first anchors and is connected to the at least one side portion.

11. The micro-electromechanical apparatus as recited in claim 10, wherein a distance from an inner side of the frame to another inner side of the frame is L, and a distance between the two first anchors is less than L/4.

12. The micro-electromechanical apparatus as recited in claim 10, wherein each of the elastic members comprises:
a fixed end connected to the corresponding first anchor;
a movable end connected to the frame; and
a connecting portion connected to the fixed end and the movable end, wherein a width of the fixed end is greater than a width of the connecting portion.

13. The micro-electromechanical apparatus as recited in claim 12, wherein a width of the movable end is greater than the width of the connecting portion.

14. The micro-electromechanical apparatus as recited in claim 10, wherein a width of the at least one side portion is greater than the width of the central portion.

15. The micro-electromechanical apparatus as recited in claim 10, further comprising at least one second anchor, wherein the at least one side portion comprises at least one opening, and the at least one second anchor is disposed in the at least one opening.

16. A micro-electromechanical apparatus adapted for measuring three-axis acceleration and comprising:
a substrate;
two first anchors disposed on the substrate, wherein a distance from each of the first anchors to a reference point of the substrate is equal;
at least one second anchor disposed on the substrate;
at least one central mass comprising a central portion and at least one side portion;
a frame surrounding the two first anchors and the at least one central mass; and
two elastic members wherein each of the two first anchors is connected to the frame through corresponding one of the two elastic members,
wherein the distance from each of the first anchors to the reference point is less than a distance from each of the first anchors to the frame, a distance from the at least one second anchor to the reference point is less than a distance from the at least one second anchor to the frame, and the central portion is disposed between the two first anchors and is connected to the at least one side portion.

17. The micro-electromechanical apparatus as recited in claim 16, wherein a distance from an inner side of the frame to another inner side of the frame is L, and a distance between the two first anchors is less than L/4.

18. The micro-electromechanical apparatus as recited in claim 16, wherein each of the elastic members comprises:
a fixed end connected to the corresponding first anchor;
a movable end connected to the frame; and
a connecting portion connected to the fixed end and the movable end, wherein a width of the fixed end is greater than a width of the connecting portion.

19. The micro-electromechanical apparatus as recited in claim 18, wherein a width of the movable end is greater than the width of the connecting portion.

20. The micro-electromechanical apparatus as recited in claim 16, further comprising at least one stationary electrode, wherein the at least one stationary electrode is connected to the at least one second anchor and is suspended above the substrate.

21. The micro-electromechanical apparatus as recited in claim 16, wherein a width of the at least one side portion is greater than a width of the central portion.

22. The micro-electromechanical apparatus as recited in claim 16, wherein the at least one side portion comprises at least one opening, and the at least one second anchor is disposed in the at least one opening.

23. The micro-electromechanical apparatus as recited in claim 16, further comprising a plurality of springs, wherein the central mass is able to sense an X-axis acceleration and a Y-axis acceleration by connecting through the plurality of springs to the frame.

24. The micro-electromechanical apparatus as recited in claim 16, wherein the two elastic members are two torsional beams, and the frame is able to sense a Z-axis acceleration by connecting through the two torsional beams to the frame.

25. The micro-electromechanical apparatus as recited in claim 24, wherein the frame is an unbalanced mass.
